(19) United States
(12) Patent Application Publication
(10) Pub. No.: US 2015/0047700 A1
(43) Pub. Date: Feb. 19, 2015

(54) CONDUCTIVE PASTE FOR SOLAR CELL ELECTRODES, SOLAR CELL, AND METHOD FOR MANUFACTURING SOLAR CELL

(71) Applicant: KYOCERA Corporation, Fushimi-ku, Kyoto-shi, Kyoto (JP)

(72) Inventors: Yoshio Miura, Higashiomi-shi (JP); Daisuke Ota, Otsu-shi (JP); Tomomi Wataya, Yokkaichi-shi (JP)

(21) Appl. No.: 14/381,961

(22) PCT Filed: Feb. 28, 2013
(86) PCT No.: PCT/JP2013/055434

§ 371 Date: Aug. 28, 2014

(30) Foreign Application Priority Data
Feb. 28, 2012 (JP) 2012-042237
May 29, 2012 (JP) 2012-122329
Jul. 30, 2012 (JP) 2012-168327
Aug. 29, 2012 (JP) 2012-189176
Sep. 27, 2012 (JP) 2012-214455
Oct. 31, 2012 (JP) 2012-239976

(51) Int. Cl. H01B 1/02; H01L 31/0216; H01L 31/0224

(52) U.S. Cl. CPC H01B 1/02; H01L 31/022425; H01L 31/02168
USPC 136/256; 438/72; 252/512; 252/514

(57) ABSTRACT

A conductive paste for solar cell electrodes according to an embodiment of the present invention comprises a glass frit containing many glass particles, and a non-glass component containing mainly at least one of silver and copper and additionally metallic element A1. The metallic element A1 is at least one selected from the group consisting of vanadium, niobium, tantalum, rhodium, rhenium, and osmium. A solar cell according to an embodiment of the present invention includes a semiconductor substrate, an antireflection film disposed in a first region on a main surface of the semiconductor substrate, and an electrode disposed in a second region different from the first region on the main surface of the semiconductor substrate and formed by firing the conductive paste for electrodes.

### TECHNICAL FIELD

The present invention relates to a conductive paste for electrodes used for forming an electrode of a solar cell, a solar cell including an electrode formed by firing the conductive paste for electrodes, and a method for manufacturing the solar cell.

### BACKGROUND ART

Many of the currently used solar cells are crystalline silicon based solar cells using crystalline silicon substrates. In a known process for manufacturing crystalline silicon based solar cells, first, an opposite conductivity type layer and an antireflection film are formed on the light-receiving side of a silicon substrate having a conductivity type. Then, a conductive paste is printed on each of at least part of the antireflection film and substantially the entire surface on the non-light-receiving side of the silicon substrate. Then, the layers of the printed conductive paste are fired, thus forming a front surface electrode on the light-receiving side and a rear surface electrode on the non-light-receiving side.

For a solar cell using a p-type silicon substrate, for example, a conductive paste mainly containing silver (hereinafter referred to as silver paste) is used as the conductive paste for electrodes for forming the front surface electrode. In the process step of forming the front surface electrode, what is called fire-through is utilized. Fire-through is a phenomenon caused by firing in which glass frit contained in the conductive paste acts to melt and remove the antireflection film under the coating of the conductive paste, consequently forming an ohmic contact between the metal component in the conductive paste and the silicon substrate.

The front surface electrode is required mainly to have good electrical properties (low contact resistance and wiring resistance) and good mechanical properties (high adhesion strength with the substrate and inner lead). The electrical output power of a solar cell is expressed by the product of short-circuit current, open-circuit voltage and fill factor (FF). The contact resistance and the wiring resistance can be main factors of the FF.

Various types of conductive pastes for forming electrodes have been proposed in order to form electrodes improved in those properties. For example, Japanese Unexamined Patent Application Publication No. 11-213754 discloses a conductive paste containing silver powder, glass powder, an organic vehicle, an organic solvent and the like, and additionally a chloride, a bromide and a fluoride. Also, Japanese Unexamined Patent Application Publication (Translation of PCT Application) No. 2011-519150 discloses a conductive paste for grid electrodes of solar cells. The conductive particles of this conductive paste contain silver particles and other particles of a metal selected from the group consisting of Pd, Ir, Pt, Ru, Ti and Co.

### SUMMARY OF INVENTION

### Problems to be Solved by the Invention

Solar cells including electrodes formed of known silver pastes are, however, insufficient in electrical properties such as the contact resistance of the electrode. Further improved electrical properties are desired.

Accordingly, it is an main object of the present invention to provide a conductive paste for electrodes capable of forming electrodes having a reduced contact resistance and useful in improving the electrical properties of solar cells, a solar cell including electrodes formed by firing the conductive paste for electrodes, and a method for manufacturing the solar cell.

### Means of solving the Problems

To achieve the above object, the conductive paste for solar cell electrodes according to an embodiment of the present invention contains a glass frit containing many glass particles, and a non-glass component containing mainly at least one of silver and copper and additionally metallic element A1. Metallic element A1 is at least one selected from the group consisting of vanadium, niobium, tantalum, rhodium, rhenium, and osmium.

A solar cell according to an embodiment of the present invention includes a semiconductor substrate, an antireflection film disposed in a first region on a main surface of the semiconductor substrate, and an electrode disposed in a second region different from the first region on the main surface of the semiconductor substrate. The electrode is formed by firing the conductive paste for solar cell electrodes.

A method for manufacturing a solar cell according to an embodiment of the present invention is intended to manufacture a solar cell including a semiconductor substrate, an antireflection film disposed in a first region on a main surface of the semiconductor substrate, and an electrode disposed in a second region different from the first region on the main surface of the semiconductor substrate. The method includes the first step of forming the antireflection film on the main surface of the semiconductor substrate, the second step of applying a conductive paste for solar cell electrodes in an electrode pattern on the antireflection film, and the third step of firing the conductive paste for electrodes to remove the portion of the antireflection film under the conductive paste for electrodes, thereby disposing the antireflection film in the first region of the semiconductor substrate and forming the electrode formed by firing the conductive paste for electrodes in the second region of the semiconductor substrate.

### Advantageous Effects of Invention

According to the conductive paste for solar cell electrodes, the solar cell and the method for manufacturing the solar cell, a solar cell having improved electrical properties and reliability can be provided.

### BRIEF DESCRIPTION OF DRAWINGS

FIG. 1 is a schematic plan view illustrating an example of a solar cell according to an embodiment of the present invention, viewed from the light-receiving side thereof.

FIG. 2 is a schematic plan view illustrating the example of the solar cell according to the embodiment of the present invention, viewed from the non-light-receiving side thereof.

FIG. 3 is a schematic sectional view illustrating the example of the solar cell according to the embodiment of the present invention, taken along the dotted chain line K-K in FIG. 1.

FIGS. 4(a) to 4(e) are schematic sectional views of a solar cell illustrating an example of a method for manufacturing the solar cell according to an embodiment of the present invention.

FIG. 5 is a schematic plan view illustrating an example of a solar cell according to an embodiment of the present invention, viewed from the rear side.

FIG. 6 is a schematic sectional view illustrating the example of the solar cell according to the embodiment of the present invention, taken along the dotted chain line L-L in FIG. 5.

FIG. 7 is a graph showing the relationship between the rhodium content and the photoelectric conversion efficiency.

FIG. 8 is a graph showing the relationship between the vanadium content and the FF retention rate.

### DESCRIPTION OF EMBODIMENTS

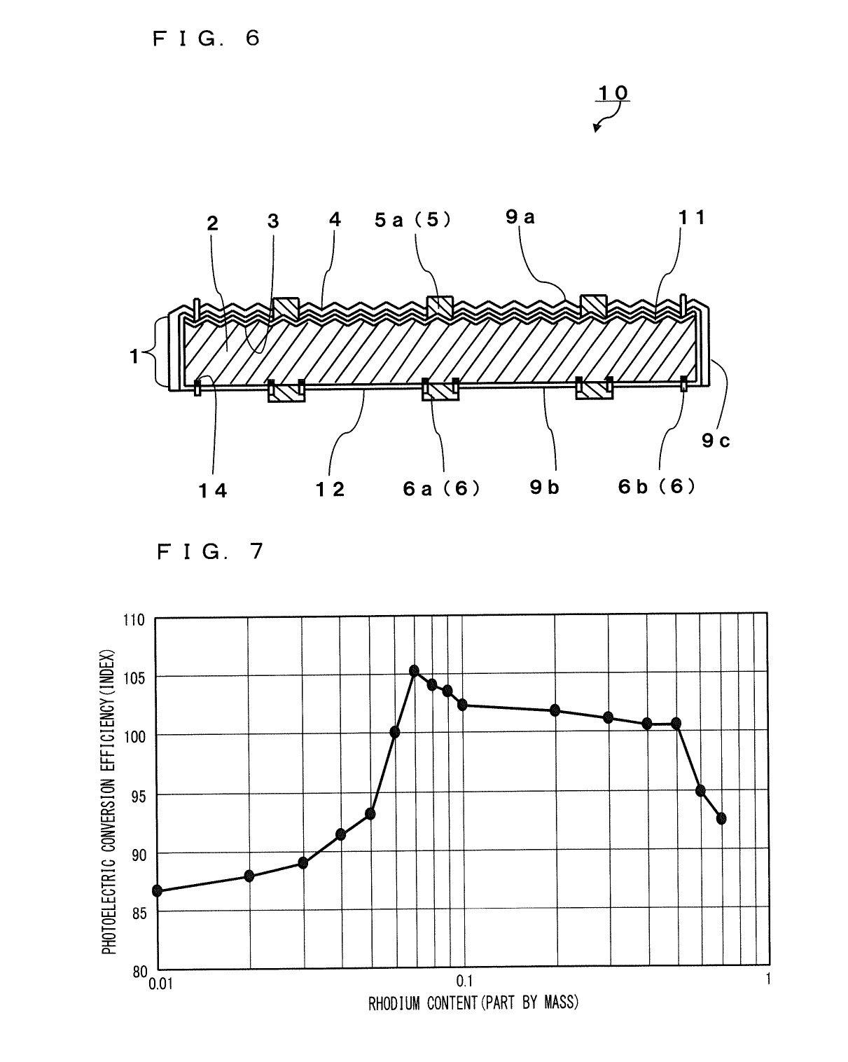

Embodiments of the conductive paste for solar cell electrodes (hereinafter referred to as conductive paste), the solar cell using the conductive paste and the method for manufacturing the solar cell, according to the present invention will now be described in detail with reference to the drawings. The parts having the same name of a solar cell are designated by the same reference numerals. Since the drawings show schematic structures, the dimensions, positional relationships and the like among the components may be varied for convenience. Also, some of the components shown in FIG. 6 are not hatched for simplicity.

<Conductive Paste>

The conductive paste used in the present embodiment contains a glass frit containing many glass particles, and a non-glass conductive component mainly containing at least one of silver and copper and additionally containing the following metallic element A1, an organic vehicle and the like. The phrase “mainly containing” implies that the content of the constituent is 50 parts by mass or more relative to 100 parts by mass of the conductive component. Metallic element A1 is at least one selected from the group consisting of vanadium, niobium, tantalum, rhodium, rhenium, and osmium.

Metallic element A1 may be added in the form of an element, an alloy or a compound. If metallic element A1 is added in the form of a compound, the compound is at least one inorganic or organic compound, such as a hydrate or oxide, selected from the group consisting of vanadium compounds, niobium compounds, tantalum compounds, rhodium compounds, rhenium compounds, and osmium compounds.

In particular, in the case of adding metallic element A1 in the form of an organic metal compound, the organic metal compound has a bond of carbon and metallic element A1 in the molecule thereof, and Examples thereof include π-cyclopentadienyl-diethylene rhodium, octa(carbonyl) dirhodium, and (benzene)-(cyclohexadiene-1,3) osmium, and in addition, organic metal compound being acetylene derivatives expressed by M(—C≡C—R)ₙ (M represents metallic element A1, R represents an alkyl group, and n represents a positive integer). In this case, the organic metal compound is dissolved in a solvent such as diethylene glycol monobutyl ether to prepare an organic metal compound-containing material. The optimum content of metallic element A1 is about 1 to 10 parts by mass in 100 parts by mass of the organic metal compound-containing material, and the optimum content of the organic metal compound is about 50 to 90 parts by mass in 100 parts by mass of the organic metal compound-containing material. The preparing of the organic metal compound-containing material, which contains metallic element A1 in the form of an organic metal compound, is advantageous in dispersing metallic element A1 in the conductive paste.

The content of at least one of above-mentioned element, an alloy and a compound is preferably in the range of 0.06 part by mass to 1 part by mass relative to 100 parts by mass of the mainly added silver (or copper or silver-copper alloy) in terms of metal content. This is because such a metal content satisfactorily produces the effect of increasing the photoelectric conversion efficiency of the solar cell. These additives may be added in the form of powder having an average particle size of about 40 μm or a mixture prepared by being added to a liquid such as diethylene glycol monobutyl ether acetate and stirred.

The use of rhodium hydrate (Rh₂O₃·5H₂O) as the inorganic metal compound is advantageous particularly because it is difficult to aggregate in the conductive paste and easy to disperse in the conductive paste. Accordingly, when the conductive paste is used for forming an electrode of a solar cell including a semiconductor substrate, a good ohmic contact can be formed at the interface between the resulting electrode and the semiconductor substrate, and thus the photoelectric conversion efficiency of the solar cell can be increased.

The non-glass component preferably contains the following metallic element A2 and the following metallic element A3 as metallic element A1 in particular. Metallic element A2 is at least one selected from the group consisting of vanadium, niobium, and tantalum. Metallic element A3 is at least one selected from the group consisting of rhodium, rhenium, and osmium.

More advantageously, vanadium and rhodium are added as metallic element A1.

The content of metallic element A2 in terms of metal content is optimally about 0.25 part by mass, and preferably in the range of 0.05 part by mass to 1 part by mass relative to 100 parts by mass of silver (or copper or silver-copper alloy). The content of metallic element A3 in terms of metal content is optimally about 0.07 parts by mass, and preferably in the range of 0.06 part by mass to 0.5 part by mass relative to 100 parts by mass of silver (or copper or silver-copper alloy). This is because metallic element A3 within this range is expected to increase the reliability of the solar cell and can suppress the degradation of the initial properties (particularly FF value) of the solar cell.

These metallic elements A2 and A3 may be used in the form of powder having a particle size (D50), which is a particle size at 50% of the integrated value (cumulative mass percentage) of the particle sizes of all the particles of the elements, of about 0.05 to 20 μm, or a mixture prepared by adding such powder to an liquid such as diethylene glycol monobutyl ether acetate and stirred. For example, when metallic element A2 is vanadium, powder of vanadium oxide, such as V₂O₅, is preferably added. For example, when metallic element A3 is rhodium, a hydrate, such as rhodium hydrate (Rh₂O₃19 5H₂O), is preferably added. Rhodium hydrates are advantageous particularly because they are difficult to aggregate in the conductive paste and easy to disperse in the conductive paste. Also, metallic elements A2 and A3 may be added in the form of an organic metal compound, as described above.

Silver (or copper or silver-copper alloy) that is a main constituent of the conductive paste used in the present embodiment may be used in the form of, but not limited to, powder such as spherical or flake-like powder. The particle size of this powder is appropriately determined depending on the conditions under which the conductive paste is applied (printed) and fired, and the appropriate average particle size is about 0.1 to 10 μm from the viewpoint of ease of printing and firing.

The metallic elements mainly added to the conductive paste may further include nickel in addition to silver and copper. In this instance, relative to 100 parts by mass of silver, 10 parts by mass to 135 parts by mass of copper, and 1 part by mass to 15 parts by mass of nickel are added. More preferably, relative to 100 parts by mass of silver, 60 parts by mass to 120 parts by mass of copper and 7 parts by mass to 11 parts by mass of nickel are added. In this instance, metallic elements A1, A2 and A3 can be added in the above-mentioned ranges relative to 100 parts by mass in total of silver, copper and nickel.

The glass material of the glass frit may be lead glass such as Al₂O₃—SO₂—PbO based glass, PbO—SiO₂—B₂O₃ based glass, PbO—SiO₂ based glass, or SiO₂—Bi₂O₃—PbO based glass, or non-lead glass such as B₂O₃—SiO₂—Bi₂O₃ based glass or B₂O₃—SiO₂—ZnO based glass.

It is advantageous that metallic element A1 is held on the surfaces of at least either the glass particles of the glass frit or the mainly added metal particles such as silver or copper. It is particularly advantageous that metallic elements A2 and A3 are held on the surfaces of at least either the glass particles or the mainly added metal particles such as silver or copper.

Thus metallic elements A2 and A3 are prevented from being aggregated and causing the conductive paste to have nonuniform concentration during preparation of the conductive paste. Thus, metallic elements A and B are more uniformly dispersed in the conductive paste. Furthermore, the metallic element A2 held on the surfaces of at least either the glass particles or the mainly added metal particles helps form a binding with the metallic element A2 interposed between the glass frit and the mainly added metal particles in the resulting electrode. This binding is more stable and stronger than the known direct binding between the glass frit and the metal particles. Consequently, the long-time reliability of the solar cell can be improved. In addition, when metallic element A3 is also held, the ease of forming an ohmic contact between the electrode and the semiconductor substrate can be kept from decreasing, and thus the initial photoelectric conversion efficiency can be prevented from decreasing.

For preparing metallic element A1 or metallic elements A2 and A3 held on the surfaces of the glass particles or metal particles of silver, copper or the like, for example, deposition precipitation method is performed. Preferably, the glass particles hold metallic element A1 on the surfaces thereof. When the glass particles hold metallic element A1 on the surfaces thereof, the glass component will form a glass layer on the surface of silicon in a firing operation, thus helping metallic element A1 improve the ease of forming an ohmic contact. Similarly, it is preferable that metallic elements A2 and A3 be held on the surfaces of the glass particles. A state of “to be held” mentioned herein refers to a state where elements do not interdiffuse with each other at the contact area of the metallic elements A1, A2 and A3 with the surfaces of the glass particles or metal particles of silver, copper or the like. It can be determined by elemental analysis of the contact area whether or not this state occurs.

For uniformly dispersing metallic element A1, or metallic elements A2 and A3, in the conductive paste, for example, the material of the metallic element may be mixed with glycerin or ethylene glycol, further mixed with the glass frit and at least either silver or copper, and then stirred, instead of being held.

This process will be described using an example using rhodium as metallic element A1.

1) First, rhodium particles are prepared. The rhodium particles preferably have particles sizes of 10 nm or less. The reason of using particles having small particle sizes of 10 nm or less is to disperse rhodium in the conductive paste as uniformly as possible.

2) The rhodium particles are slowly added to pure water and stirred to yield an aqueous dispersion. The content of the rhodium particles in the aqueous dispersion is about 0.1 to 0.3 g relative to 100 g of pure water. The reason why the aqueous dispersion is prepared by adding rhodium particles to pure water is that if the rhodium particles of 10 nm or less in particle size are directly added to glycerin or ethylene glycol, the rhodium particles are likely to aggregate, and thus a satisfactory dispersion liquid is not easily prepared.

3) Subsequently, glycerin or ethylene glycol is added to the aqueous dispersion, followed by stirring. The amount of glycerin or ethylene glycol at this time is preferably about 5 to 20 parts by mass relative to 100 parts by mass of the aqueous dispersion. The reason of using glycerin or ethylene glycol is that they are easily dissolved in water and also well dissolved in the solvent of the conductive paste such as terpineol or diethylene glycol monobutyl ether. More specifically, in view of solubility parameter (SP value), water (SP value: 23.4) and diethylene glycol monobutyl ether (SP value: 8.9) or the like have a large difference in SP value and are accordingly difficult to dissolve in each other. If the aqueous dispersion is directly added to the conductive paste, rhodium particles are not uniformly dispersed in the conductive paste, whereas glycerin (SP value: 17.2) or ethylene glycerol (SP value: 14.2) are well dissolved in both water and diethylene glycol monobutyl ether because of the SP value between that of water and that of diethylene glycol monobutyl ether or the like.

4) The mixed liquid of the aqueous dispersion and glycerin or ethylene glycol is heated to about 100° C. to evaporate water. After water has been completely evaporated by heating and it has been confirmed that the mass of the liquid does not vary, the heating is stopped. Thus, the solvent is substituted to yield a dispersion liquid in which rhodium particles are substantially uniformly dispersed in glycerin or ethylene glycol.

5) Subsequently, the above-prepared dispersion liquid, in which rhodium particles are dispersed in glycerin or ethylene glycol is mixed with a paste prepared by mixing at least one of silver and copper, a glass frit and an organic vehicle, followed by stirring. Thus, the rhodium particles are uniformly dispersed in the conductive paste.

In the case of adding metal element A2, powder of the metallic element having a particle size (D50), which is a particle size at 50% of the integrated value (cumulative mass percentage) of the particle sizes of all the particles of the metallic element, of about 0.05 to 20 μm may be directly added to the paste. It is however preferable that metallic element A2 be held in the glass particles as described above before being added to the paste. Metallic element A2 in such a state can be uniformly dispersed in the conductive paste.

In the conductive paste of the present embodiment, the glass frit content is preferably in the range of 1 part by mass to 15 parts by mass, optimally in the range of 4.5 parts by mass to 6.5 parts by mass, relative to 100 parts by mass of silver (or copper or silver-copper alloy). By controlling the glass frit content in such a range, the adhesion strength and contact resistance between the semiconductor substrate and the electrode become good.

The organic vehicle is prepared by dissolving a resin component used as a binder in an organic solvent. Examples of the organic binder include cellulose-based resins, acrylic resins, alkyd resins and the like, and examples of the organic solvent include terpineol, diethylene glycol monobutyl ether acetate and the like.

According to the present embodiment, the addition of metallic element A2 helps form a binding with the metallic element A2 interposed between the glass frit and silver (or copper or silver-copper alloy) in the resulting electrode. This binding is more stable and stronger than the known direct binding between the glass frit and silver (or copper or silver-copper alloy). Consequently, the long-time reliability of the solar cell is improved.

In particular, it is advantageous to add metallic element A2 so as to present among the glass particles of the glass frit. This allows metallic element A2 to be uniformly dispersed in the conductive paste, and enhances the binding strength between the silicon and the interdiffused glass particles and metal particles such as silver or copper to stabilize the adhesion between the silicon and the electrode. Thus, the reliability of the solar cell can be enhanced. In this instance, the content of metallic element A2 in terms of metal content is optimally about 5 parts by mass, and preferably in the range of 0.2 part by mass to 20 parts by mass relative to 100 parts by mass of the glass frit. This is because metallic element A2 within this range is expected to increase the reliability of the solar cell and can suppress the degradation of the initial properties (particularly FF value) of the solar cell.

By further adding metallic element A3, the ease of forming an ohmic contact between the silicon substrate and the electrode formed under the condition where metallic element A2 has been added can be kept from decreasing, and thus the initial photoelectric conversion efficiency can be prevented from decreasing.

In the present embodiment, in particular, since the conductive paste contains mainly silver (or copper or silver-copper alloy) and additionally the above-described metallic elements A2 and A3, the catalysis of these constituents helps the glass frit melt and remove the antireflection film. Consequently, the output power characteristics (particularly fill factor (FF)) of the solar cell can be improved, and the photoelectric conversion efficiency thereof can be increased.

<Basic Structure of Solar Cell Element>

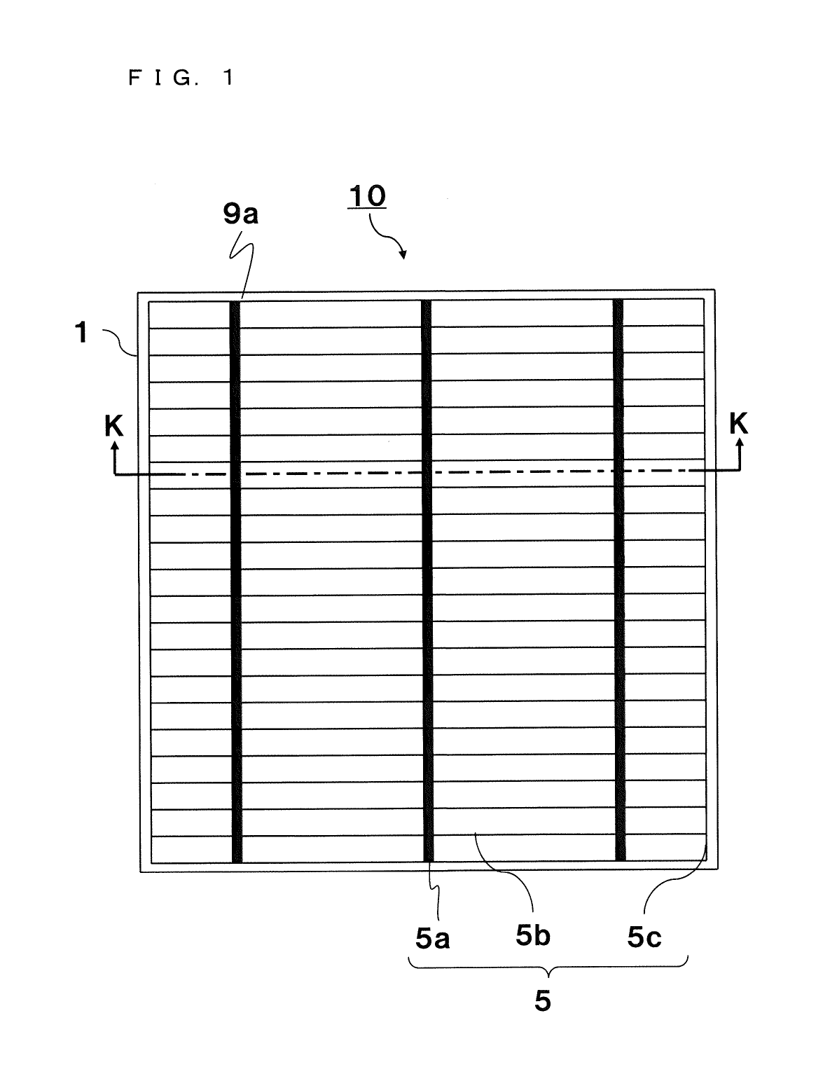

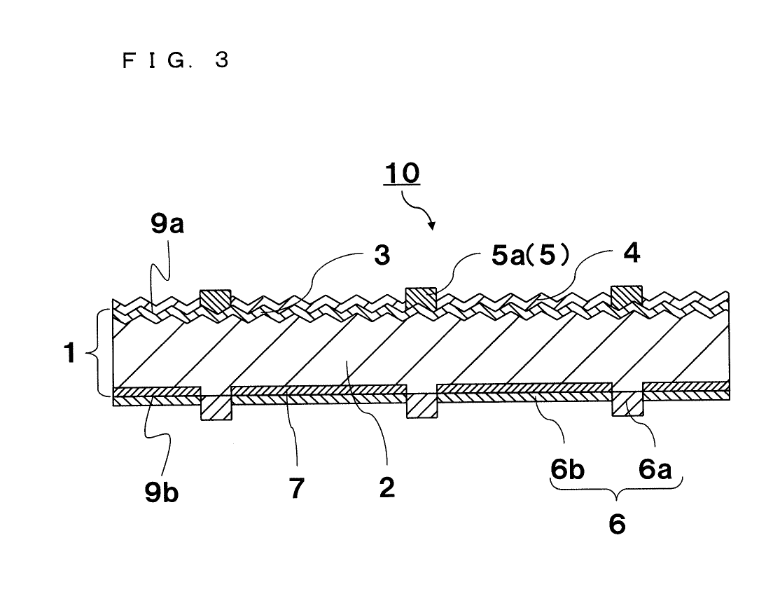

The basic structure of a solar cell element that is one of the solar cells will now be described. As shown in FIGS. 1 to 3, the solar cell element 10 has a front surface (light-receiving surface, upper surface in FIG. 3) 9a as a main surface through which light enters the element, and a rear surface (non-light-receiving surface, lower surface in FIG. 3) 9b opposite the front surface. The solar cell element 10 includes an antireflection layer 4 as an antireflection film and a front surface electrode 5 on the front surface 9a of the semiconductor substrate 1, and a rear surface electrode 6 on the rear surface 9b of the semiconductor substrate 1. The semiconductor substrate 1 includes a one conductivity type layer 2 and an opposite conductivity type layer 3 provided on the front surface 9a side of the one conductivity type layer 2.

<Specific Embodiment of Solar Cell Element>

A specific embodiment of the solar cell element will now be described. A monocrystalline or polycrystalline silicon substrate doped with a predetermined dopant so as to have a conductivity type (for example, p-type) is suitably used as the semiconductor substrate 1. Te semiconductor substrate 1 has a specific resistance of about 0.8 to 2.5 μ·cm. Also, the preferred thickness of the semiconductor substrate 1 may be 250 μm or less, and is more preferably 150 μm or less. The shape of the semiconductor substrate 1 in plan view is preferably, but is not limited to, tetragonal from the viewpoint of manufacturing the solar cell element, arranging many solar cell elements into a solar cell module, and the like.

In the following description, a p-type silicon substrate is used as the semiconductor substrate 1. To impart the p-type conductivity to the first semiconductor layer 1, for example, boron or gallium is suitable as a dopant element.

The opposite conductivity type layer 3 forming a pn junction with the one conductivity type layer 2 has a conductivity type opposite to the conductivity type of the one conductivity type layer 2 (semiconductor substrate 1) and is disposed at the front surface 9a side of the semiconductor substrate 1. If the one conductivity type layer 2 is p-type, the opposite conductivity type layer 3 is n-type. For a p-type semiconductor substrate 1, the opposite conductivity type layer 3 can be formed by diffusing a dopant such as phosphorus in the front surface 9a side of the silicon substrate 1.

The antireflection layer 4 reduces the reflection of light from the front surface 9a, thus increasing the amount of light absorbed to the semiconductor substrate 1. The antireflection layer thus increases the number of electron-hole pairs produced by light absorption, contributing to the increase in the conversion efficiency of the solar cell. The antireflection layer 4 may be made of, for example, a silicon nitride film, a titanium oxide film, a silicon oxide film or an aluminum oxide film, or a composite of these films. The thickness of the antireflection layer 4 is appropriately set according to the material and so that some incident light rays do not reflect. Preferably, the antireflection layer 4 on the semiconductor substrate 1 has a refractive index of about 1.8 to 2.3 and a thickness of about 500 to 1200 Å. The antireflection layer 4 can function as a passivation film for minimizing decrease in conversion efficiency resulting from the recombination of carriers at the interface thereof with the semiconductor substrate 1 and grain boundaries.

A BSF (Back-Surface-Field) region 7 has a function of creating an inner electric field at the rear surface 9b side of the semiconductor substrate 1 to minimize decrease in conversion efficiency resulting from the recombination of carriers in the vicinity of the rear surface 9b. Although the BSF region 7 has the same conductivity type as the one conductivity type layer 2 of the semiconductor substrate 1, the majority carrier concentration of the BSF region 7 is higher than that of the one conductivity type layer 2. This implies that the BSF region 7 contains a dopant element with a higher concentration than the dopant element implanted to the one conductivity type layer 2. When the semiconductor substrate 1 is p-type, the BSF region 7 is preferably doped to a dopant concentration of about 1×10¹⁸ to 5×10²¹ atoms/cm³ by, for example, diffusing the dopant element such as boron or aluminum into the rear surface 9b side.

As shown in FIG. 1, the front surface electrode 5 includes front surface power extraction electrodes (bas bar electrodes) 5a and front surface collector electrodes (finger electrodes) 5b. At least some of the front surface power extraction electrodes 5a intersect the front surface collector electrodes 5b. The front surface power extraction electrodes 5a each have a width of, for example, about 1.3 to 2.5 mm.

The front surface collector electrodes 5b each have a line width of about 50 to 200 μm, thinner than the front surface power extraction electrodes 5a. Also, the front surface collector electrodes 5b are arranged at intervals of about 1.5 to 3 mm.

The thickness of the front surface electrode 5 is about 10 to 40 μm. The front surface electrode 5 may be formed by, for example, applying a conductive paste containing silver (or copper or silver-copper alloy) powder, a glass frit, an organic vehicle and the like in a predetermined pattern by screen printing or the like, and then firing the applied paste. In the formation of the front surface electrode 5, the glass frit melted by firing melts and removes the antireflection layer 4 and, further, reacts with the uppermost layer of the semiconductor substrate 1 to adhere there, thus helping the formation of electrical contact with the semiconductor substrate 1 and maintaining mechanical adhesion strength.

The front surface electrode 5 may have a structure including a base electrode layer formed as described above and a conductive plating electrode layer formed by plating on the base electrode layer.

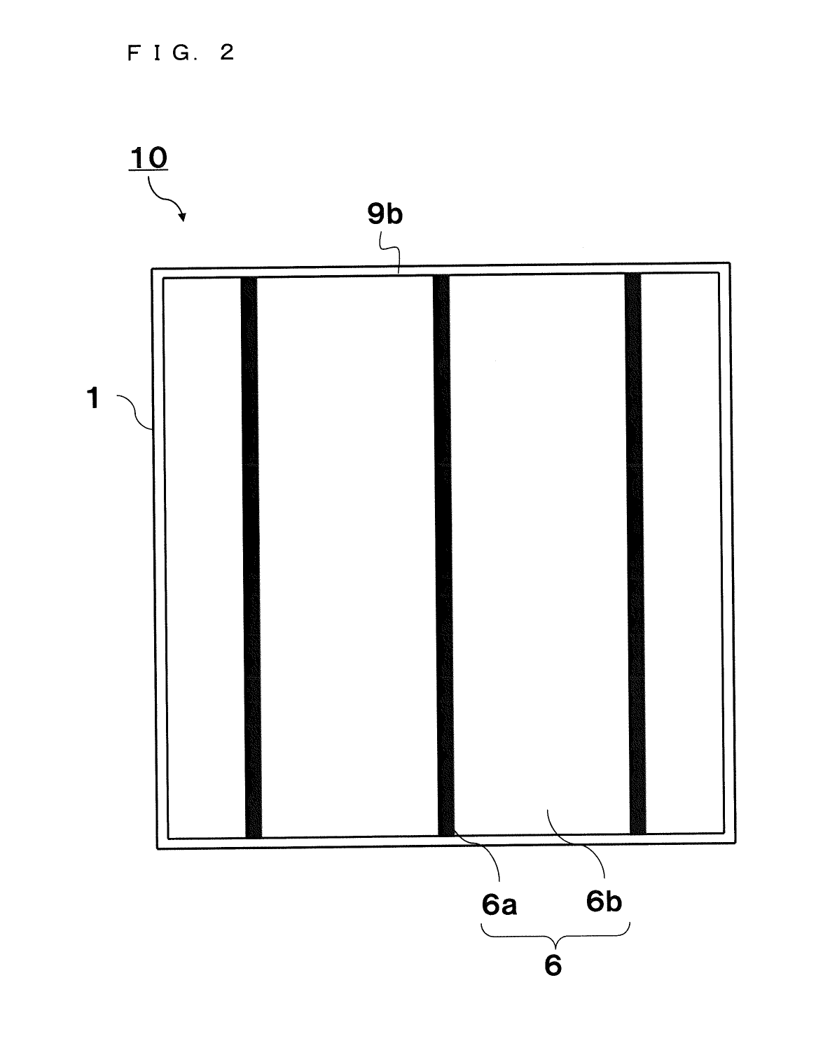

The rear surface electrode 6 includes rear surface power extraction electrodes 6a and rear surface collector electrodes 6b, as shown in FIG. 2. In the present embodiment, the rear surface power extraction electrode 6a each have a thickness of about 10 to 30 μm and a width of about 1.3 to 7 mm. The rear surface power extraction electrode 6a may be formed by, for example, applying a paste of silver (or copper or silver-copper alloy) in a predetermined pattern, followed by firing. The rear surface collector electrodes 6b, each having a thickness of about 15 to 50 μm, are disposed over substantially the entire rear surface 9b of the semiconductor substrate 1 except the regions of the rear surface power extraction electrodes 6a. The rear surface collector electrodes 6b can be formed by, for example, applying an aluminum paste in a predetermined pattern, followed by firing.

The conductive paste of the present embodiment is also suitable for forming the rear surface power extraction electrodes 6a. The major characteristics required of the rear surface power extraction electrode 6a are adhesion strength with the semiconductor substrate 1, good electric contact with the rear surface collector electrodes 6b, and the resistance of the electrode itself. By using the conductive paste of the present embodiment, rear surface power extraction electrodes 6a improved in these characteristics can be formed.

<Method for Manufacturing Solar Cell Element>

A method for manufacturing the solar cell element 10 will now be described. As described above, the solar cell element 10 includes the semiconductor substrate made of, for example, silicon, the antireflection layer 4 disposed in first regions on a main surface of the semiconductor substrate 1, and the electrode disposed in second regions on the main surface and formed by firing the above-described conductive paste. A method for manufacturing such a solar cell element 10 includes the first step of forming the antireflection layer 4 on the main surface of the semiconductor substrate 1, the second step of applying the above-described conductive paste on the antireflection layer 4, and the third step of firing the conductive paste to remove the portion of the antireflection layer 4 underlying the conductive paste, thereby arranging the antireflection layer 4 in the first regions of the semiconductor substrate 1 and forming the electrode in the second regions of the semiconductor substrate 1.

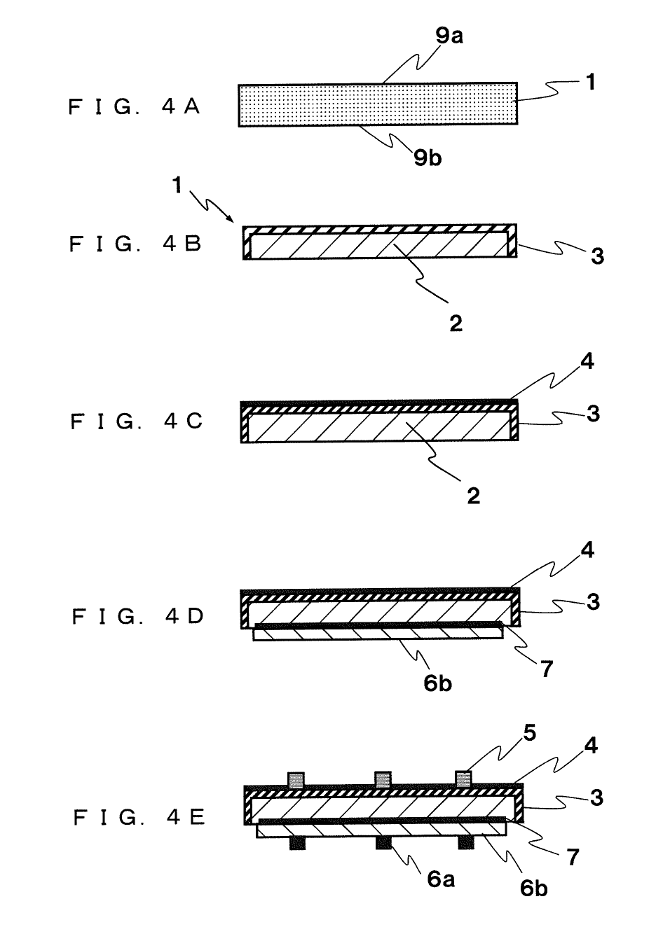

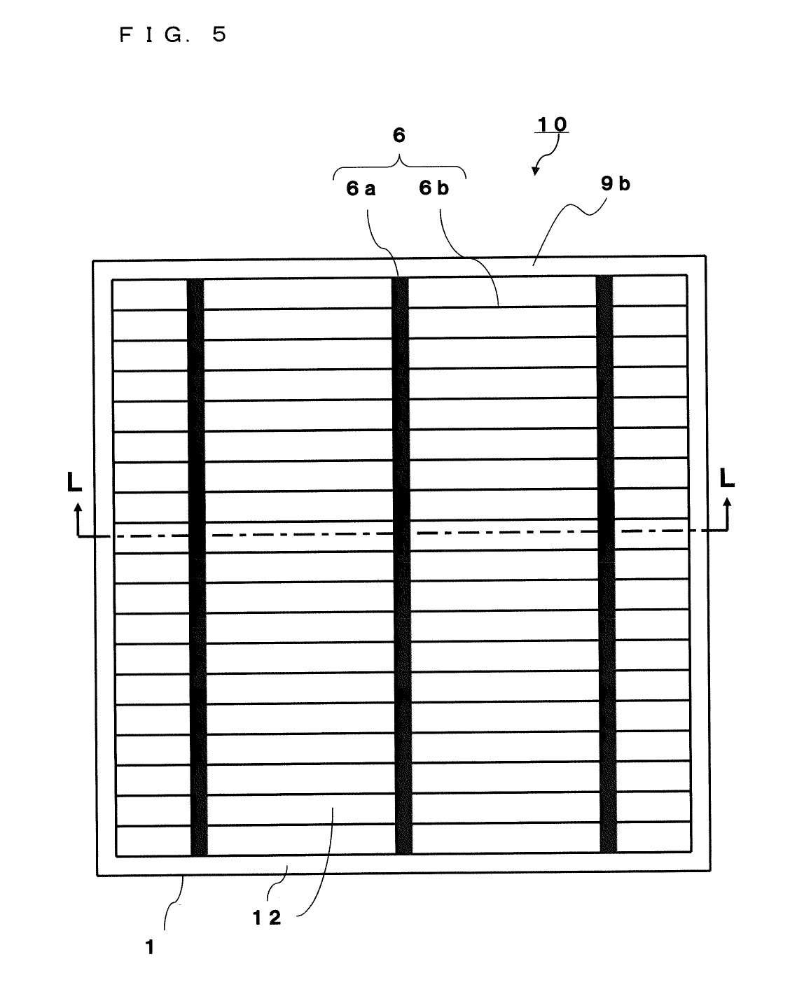

The method for manufacturing will be further described more specifically. First, a semiconductor substrate 1 defining a one conductivity type layer is prepared, as shown in FIG. 4(a). When a monocrystalline silicon substrate is used as the semiconductor substrate 1, it is formed by, for example, FZ (floating zone) method, CZ (Czochralski) method, or the like. When a polycrystalline silicon substrate is used as the semiconductor substrate 1, it is formed by, for example, casting or the like. In the following description, a p-type polycrystalline silicon substrate is used as the semiconductor substrate.

First, an ingot of polycrystalline silicon is prepared by, for example, casting. Then, the ingot is sliced to a thickness of, for example, 250 μm or less to form a semiconductor substrate 1. Desirably, the surface of the semiconductor substrate 1 is then very slightly etched with NaOH, KOH, fluoronitric acid or the like to remove a mechanically damaged or contaminated layer from the cutting plane of the semiconductor substrate 1. After this etching operation, desirably, a fine relief structure (texture) is formed on the surface of the semiconductor substrate 1 by wet etching or dry etching. This texture minimizes the reflectance of the front surface 9a, consequently increasing the conversion efficiency of the solar cell. The above-mentioned operation of removing the mechanically damaged layer may be omitted depending on the method or conditions for forming the texture.

Subsequently, an n-type opposite conductivity type layer 3 is formed in the surface layer at the front surface 9a side of the semiconductor substrate 1, as shown in FIG. 4(b). The opposite conductivity type layer 3 is formed by an application and thermal diffusion process in which a P₂O₅ paste is applied to the surface of the semiconductor substrate 1 and is then thermally diffused, a gas phase thermal diffusion process using phosphoryl chloride (POCl₃) gas as a diffusion source, or an ion implantation process in which phosphorus ions are directly implanted. The opposite conductivity type layer 3 is formed to a depth of about 0.1 to 1 μm with a sheet resistance of about 40 to 150 Ω/sq. The formation of the opposite conductivity type layer 3 is not limited to the above-described process. For example, a hydrogenated amorphous silicon film or a crystalline silicon film including a microcrystalline silicon film may be formed by a thin-film technique. Also, an i-type silicon region may be formed between the semiconductor substrate 1 and the opposite conductivity type layer 3.

If an opposite conductivity type layer is formed at the rear surface 9b side when the opposite conductivity type layer 3 is formed, only the opposite conductivity layer at the rear surface 9b side is removed to expose the p-type conductivity region by etching. For example, only the rear surface 9b side of the semiconductor substrate 1 is soaked in a fluoronitric acid solution to remove the opposite conductivity type layer 3. Then, phosphate glass, which has been attached to the surface of the semiconductor substrate 1 when the opposite conductivity type layer 3 has been formed, is removed by etching. Alternatively, the rear surface 9b side is covered with a diffusion mask in advance, and then the opposite conductivity type layer 3 is formed by gas phase thermal diffusion or the like, followed by removing the diffusion mask. This process can also form the same structure.

Thus, the semiconductor substrate 1 including the one conductivity type layer 2 and the opposite conductivity type layer 3 can be prepared.

Then, as shown in FIG. 4(c), an antireflection layer 4 as an antireflection film is formed. For forming the antireflection layer 4, a film of silicon nitride, titanium oxide, silicon oxide, aluminum oxide, or the like is formed by PECVD (plasma enhanced chemical vapor deposition), thermal CVD, vapor deposition, sputtering or the like. In the case of, for example, forming a silicon nitride antireflection layer 4 by PECVD, the antireflection layer 4 is formed by depositing plasma of a mixed gas of silane (SiH₄) and ammonia (NH₃) produced by subjecting the mixed gas diluted with nitrogen (N₂) to glow discharge decomposition in a reaction chamber of about 500° C.

Subsequently, rear surface collector electrodes 6b and BSF regions 7 are formed at the rear surface 9b side of the semiconductor substrate 1, as shown in FIG. 4(d). In this process, for example, aluminum paste may be applied to the rear surface by printing, and then the aluminum is diffused into the semiconductor substrate 1 by firing at a temperature of about 600 to 850° C., thereby forming rear surface collector electrodes 6b and BSF regions 7. The process of printing the aluminum paste followed by firing allows desired diffusion regions to be formed only at the printed surface. In addition, this process does not require that the n-type opposite conductivity type layer formed at the rear surface 9b side when the opposite conductivity type layer 3 is formed be removed, but only requires pn separation (to separate the continuous pn junction) at only the outer region of the rear surface 9b by using a laser or the like.

The aluminum paste for forming the rear surface collector electrodes 6b contains, for example, metal powder mainly containing aluminum, a glass frit, and an organic vehicle. This conductive paste is applied over substantially the entire surface of the rear surface 9b except the parts of the portions in which the rear surface power extraction electrodes 6a will be formed. The application of the paste may be performed by, for example, screen printing. After the application of the conductive paste, preferably, the solvent is evaporated at a predetermined temperature to dry the conductive paste. Consequently, the conductive paste becomes difficult to adhere to other parts while handled.

The formation of the BSF regions 7 is not limited to the above-described process, and may be performed by a thermal diffusion process at a temperature of about 800 to 1100° C. using boron tribromide (BBr₃) as a diffusion source. Alternatively, a hydrogenated amorphous silicon film, crystalline silicon film including a microcrystalline silicon film or the like may be formed by a thin-film technique. Also, an i-type silicon region may be formed between the one conductivity type layer 2 and the BSF regions 7.

Then, the front surface electrode 5 and the rear surface power extraction electrodes 6a are formed, as shown in FIG. 4(e).

The front surface electrode 5 is formed using the conductive paste containing a non-glass component containing mainly silver (or copper or silver-copper alloy) and additionally the above-described metallic elements A2 and A3, a glass frit, and an organic vehicle, as described above. The conductive paste is applied to the front surface 9a of the semiconductor substrate 1 to form a predetermined electrode pattern. Subsequently, the electrode pattern is fired at temperatures up to 600 to 850° C. for about several tens of seconds to several tens of minutes, thereby forming the front surface electrode 5 on the semiconductor substrate 1.

The application of the conductive paste may be performed by, for example, screen printing. After the application of the conductive paste, desirably, the solvent is evaporated to dry the conductive paste at a predetermined temperature. During firing, the glass frit and the antireflection layer 4 react with each other at high temperature to cause a fire-through phenomenon, thereby forming electrical and mechanical contacts between the front surface electrode 5 and the semiconductor substrate 1. The front surface electrode 5 may have a structure including a base electrode layer formed as described above and a plating electrode layer formed by plating on the base electrode layer.

The rear surface power extraction electrodes 6a are formed using a silver (or copper or silver-copper alloy) paste containing a metal powder mainly containing silver, a glass frit and an organic vehicle. This silver (or copper or silver-copper alloy) paste is applied in a predetermined pattern in advance. By applying the silver (or copper or silver-copper alloy) paste so as to come in contact with part of the aluminum paste, the rear surface power extraction electrodes 6a and the rear collector electrodes 6b overlap partially with each other, thereby forming electrical contacts. This application may be performed by, for example, screen printing. After the application, the solvent is evaporated to dry the paste at a predetermined temperature.

From the viewpoint of reducing the number of parts of the solar cell in the manufacturing process, it is preferable to use the above-mentioned conductive paste, which is used for forming the surface electrode 5, for forming the rear surface power extraction electrodes 6a.

Then, the semiconductor substrate 1 is fired in a firing furnace at temperatures up to 600 to 850° C. for about several tens of seconds to several tens of minutes, thereby forming the rear surface electrode 6 on the rear surface 9b side of the semiconductor substrate 1. Either the paste of the rear surface power extraction electrodes 6a or the paste of the rear surface collector electrodes 6b may be first applied, and the firing of the pastes may be performed at one time. One of the pastes may be first applied and fired, and then the other may be applied and fired.

The rear surface electrode 6 may be formed by thin-film forming method such as vapor deposition or sputtering, or by plating.

The conductive paste and the method for manufacturing a solar cell element of the above-described embodiment can achieve a solar cell element 10 improved in electrical characteristics such as contact resistance and wiring resistance.

<Modification 1>

The present invention is not limited to the above-described embodiment, and various modifications and changes may be made within the scope of the present invention, as will be described below.

For example, the semiconductor substrate 1 may be provided with a passivation film at the rear surface 9b side thereof. The passivation film functions to reduce the recombination of carriers at the rear surface 9b as a rear surface of the semiconductor substrate 1. The passivation film may be made of silicon nitride, silicon oxide, titanium oxide, aluminum oxide or the like. The passivation film may be formed to a thickness of about 100 to 2000 Å by PECVD, thermal CVD, vapor deposition, sputtering or the like. Thus, the rear surface 9b side of the semiconductor substrate 1 has a structure capable of being used for a PERC (Passivated Emitter and Rear Cell) structure or a PERL (Passivated Emitter Rear Locally-diffused) structure.

The conductive paste of the present invention can be also suitably used for the step of forming an electrode after the formation of the rear surface passivation layer by applying a conductive paste on the antireflection film in the first regions on the front surface 9a of the semiconductor substrate 1 and firing the applied conductive paste. In the case of applying the conductive paste on the antireflection layer 4 on the front surface 9a after the passivation film is formed at the rear surface 9b side, and then firing the conductive paste, the effect of the passivation film at the rear surface is reduced if the peak firing temperature is over 800° C. However, the conductive paste of the embodiment, which contains metallic elements A2 and A3, can be fired at 800° C. or less (for example, 600 to 780° C.) without reducing the initial photoelectric conversion efficiency or degrading the long-time reliability, thus being fired without reducing the effect of the passivation film.

Linear auxiliary electrodes 5c intersecting the front surface collector electrodes 5b may be provided at both ends intersecting the longitudinal direction of the front surface collector electrodes 5b. This is advantageous because even if some of the front surface collector electrodes 5b are broken, increase in resistance is minimized and current can flow to the front surface power extraction electrodes 5a through the other front surface collector electrodes 5b.

The rear surface electrode 6 may have the structure including rear surface power extraction electrodes 6a and a plurality of linear rear surface collector electrodes 6b intersecting the rear surface power extraction electrodes 6a as with the front surface electrode 5, and may include a base electrode layer and a plating electrode layer.

A region (selective emitter region) having the same conductivity type as the opposite conductivity type layer 3 and more heavily doped than the opposite conductivity type layer 3 may be formed at the position of the semiconductor substrate 1 where the front surface electrode 5 is formed. At this time, the selective emitter region is formed with a lower sheet resistance than the opposite conductivity type layer 3. By forming the selective emitter region with a lower sheet resistance, the contact resistance with the electrode can be reduced. For example, the selective emitter region may be formed after the formation of the opposite conductivity type layer 3 by an application and thermal diffusion process or a gas phase thermal diffusion process, by irradiating the semiconductor substrate 1 with laser light corresponding to the shape of the front surface electrode 5 with phosphate glass remaining therein and thus rediffusing phosphorus from the phosphate glass to the opposite conductivity type layer 3.

Although the above-described embodiment illustrates the case of using a silicon substrate as the semiconductor substrate, the semiconductor substrate may be a substrate having chemical properties similar to those of silicon without being limited to a silicon substrate.

<Modification 2>

FIG. 5 is a schematic plan view of an example of another solar cell element 10 viewed from the rear surface 9b side, and FIG. 6 is a schematic sectional view taken along line A-A in FIG. 5. As shown in FIGS. 5 and 6, the solar cell element 10 is provided with passivation layers over substantially the entireties of both of the front surface 9a side and rear surface 9b side of the semiconductor substrate 1. In other words, a first passivation layer 11 is disposed on the n-type semiconductor region 3, and a second passivation layer 12 is disposed on the p-type semiconductor region 2. The first passivation layer 11 and the second passivation layer 12 can be formed over all the surfaces of the semiconductor substrate 1 by, for example, using ALD (Atomic Layer Deposition). Hence, the side surfaces 9c of the semiconductor substrate 1 are provided with the passivation layer made of aluminum oxide or the like. Furthermore, the first passivation layer 11 is provided with an antireflection layer 4 thereon.

For forming a passivation layer made of, for example, aluminum oxide by ALD, the following process is applied.

First, the above-described semiconductor substrate 1 made of, for example, polycrystalline silicon is placed in a deposition chamber and heated to a substrate temperature of 100 to 300° C. Subsequently, an aluminum raw material, such as trimethylaluminum, is supplied over the semiconductor substrate 1 for a period of 0.5 second with a carrier gas, such as argon or nitrogen gas, so that all the surfaces of the semiconductor substrate 1 adsorb the aluminum raw material (step 1).

Then, the internal space of the deposition chamber is purged by nitrogen gas for a period of 1 second to remove the aluminum raw material from the chamber and remove all the aluminum raw material adsorbed to the surface of the semiconductor substrate 1 except the component adsorbed at the atomic layer level (step 2).

Then, water or an oxidizing agent such as ozone gas is supplied into the deposition chamber for a period of 4 seconds to remove CH₃ as the alkyl group of trimethylaluminum as the aluminum raw material and to oxidize the dangling bond of aluminum, thereby forming an aluminum oxide atomic layer on the semiconductor substrate 1 (step 3).

Then, for example, the internal space of the deposition chamber is purged by nitrogen gas for a period of 1.5 seconds to remove the oxidizing agent from the chamber and remove all the substances such as a portion of the oxidizing agent not used for the reaction except aluminum oxide at the atomic layer level (step 4).

The sequence from Step 1 to Step 4 is repeated, thereby forming an aluminum oxide layer having a predetermined thickness. Hydrogen may be added to the oxidizing agent used in Step 3. This helps introduce hydrogen to the aluminum oxide layer, consequently enhancing the effect of hydrogen passivation.

Since the aluminum oxide layer is formed along the fine relief pattern at the surface of the semiconductor substrate 1 by applying ALD to the formation of the first passivation layer 11 and the second passivation layer 12, the effect of surface passivation can be enhanced. Also, by forming the antireflection layer 4 by a method other than ALD, such as PECVD or sputtering, a desired thickness can be rapidly formed, and accordingly, productivity is increased.

Subsequently, a front surface electrode 5 (first power extraction electrodes 5a, first collector electrodes 5b) and a rear surface electrode 6 (second power extraction electrodes 6a, second collector electrodes 6b) are formed as below.

The front surface electrode 5 will be described first. For example, the front surface electrode 5 is formed using a conductive paste containing a non-glass component containing mainly silver and additionally metallic elements A2 and A3, a glass frit, and an organic vehicle, as described above. The front surface electrode 5 is formed by applying the conductive paste on the antireflection film 4 at the front surface 9a of the semiconductor substrate 1, and then firing the conductive paste at temperatures up to 600 to 800° C. for about several tens of seconds to several tens of minutes.

Next, BSF regions 14 and the rear surface electrode 6 will be described. An aluminum paste containing a glass frit is applied directly in predetermined regions on the second passivation layer 12, and is then subjected to a fire-through method in which the applied paste is heated to temperatures up to 600 to 800° C. Consequently, the applied paste passes through the second passivation layer 12 to form BSF regions 14 at the rear surface 9b side of the semiconductor substrate 1, and aluminum layers are each formed on the BSF regions 14. The aluminum layers may be used as the rear surface collector electrodes 6b. The BSF regions are formed, for example, within the region at the rear surface 9b where part of each rear surface power extraction electrode 6a is formed in the manner as shown in FIG. 5. For forming the rear surface power extraction electrodes 6a, it is also desirable to use the above-described conductive paste containing a non-glass component containing mainly silver and additionally metallic elements A2 and A3, a glass frit, and an organic vehicle.

The conductive paste is applied on the second passivation layer 12 in a pattern of three linear lines, each partially in contact with the rear surface collector electrodes 6b as shown in FIG. 5. Then, the applied conductive paste is fired at temperatures up to 600 to 800° C. for about several tens of seconds to several tens of minutes, thereby forming rear surface power extraction electrodes 6a. The application of the conductive paste may be performed by, for example, screen printing. After the application, the solvent may be evaporated at a predetermined temperature to dry the coating. The rear surface power extraction electrodes 6a are brought into contact with the aluminum layers, thus connected to the rear surface collector electrodes 6b.

The silver rear surface power extraction electrodes 6a may be first formed, and then the aluminum rear surface collector electrodes 6b may be formed. The rear surface power extraction electrodes 6a are not necessarily in direct contact with the semiconductor substrate 1, and a second passivation layer 12 may be disposed between the second power extraction electrodes 6a and the semiconductor substrate 1.

Even if the passivation layers 11 and 12 are disposed over substantially the entire surfaces of the semiconductor substrate 1, as described above, firing can be performed at temperatures of 800° C. or less without reducing the effect of passivation films.

### EXAMPLES

Specific examples of the above-described embodiments will now be described below.

<Case 1>

First, many polycrystalline silicon substrates each of a square of 156 mm on a side with a thickness of about 200 μm were prepared as the semiconductor substrates. These silicon substrates were doped with boron. Thus, p-type polycrystalline silicon substrates having a specific resistance of about 1.5 Ω·cm were used. The damaged layer of surfaces of the silicon substrates were etched with a NaOH aqueous solution for cleaning.

Then, a relief structure (texture) was formed at the front surface of each of the silicon substrates by RIE (Reactive Ion Etching).

Subsequently, phosphorus was diffused by gas phase thermal diffusion using phosphoryl chloride (POCl₃) as a diffusion source to form an n-type opposite conductivity type layer having a sheet resistance of about 90 Ω/sq. on the surface of the silicon substrate. The portions of the opposite conductivity type layer formed on the side and rear surfaces of the silicon substrate were removed with a fluoronitric acid solution, and then, phosphate glass remaining on the second semiconductor layer was removed with a hydrofluoric acid solution.

Subsequently, a first and a second aluminum oxide passivation layer were formed over the entireties of the surfaces of the silicon substrate by ALD, and a silicon nitride antireflection layer 4 was formed on the first passivation layer by plasma CVD. The average thickness of the first and second passivation layers was 35 nm, and the average thickness of the antireflection layer was 45 nm.

For forming the front surface electrode, a silver paste prepared by mixing silver powder, Al₂O₃—SiO₂—PbO based glass frit and an organic vehicle in proportions by mass of 85:5:10 and further mixing 0.01 part by mass to 0.7 part by mass of elemental rhodium relative to 100 parts by mass of silver was applied in a liner pattern as shown in FIG. 1 by screen printing, followed by drying.

Then, an aluminum paste was applied in a pattern of the rear surface collector electrodes 6b as shown in FIG. 5 on the rear surface side of the silicon substrate, followed by drying. Then, the same silver paste as used for the front surface electrode 5 was applied in a pattern of the second power extraction electrodes 6a as shown in FIG. 5, then dried, and fired for 3 minutes under the condition of 750° C. in peak temperature.

Thus solar cell elements were prepared.

For each rhodium content, 30 solar cell elements were prepared, and the output power characteristic (photoelectric conversion efficiency) of each solar cell element was measured for evaluation. The results are shown in FIG. 7. The photoelectric conversion efficiencies shown in FIG. 7 are represented by index with respect to the value when the rhodium content was 0.06 part by mass, at which the index is 100. These values were measured under the conditions of AM (Air Mass) 1.5 and irradiation of 100 mW/cm² in accordance with JIS C 8913, and then each average thereof is calculated.

The results in FIG. 7 show that when the rhodium content was in the range of 0.06 part by mass to 0.5 part by mass, the photoelectric conversion efficiency of the solar cell was markedly increased. Also, when the rhodium content was 0.07 part by mass, the photoelectric conversion efficiency reached the highest.

<Case 2>

First, the same semiconductor substrate as used in Case 1 was subjected to the steps before forming electrodes in the same manner as in Case 1.

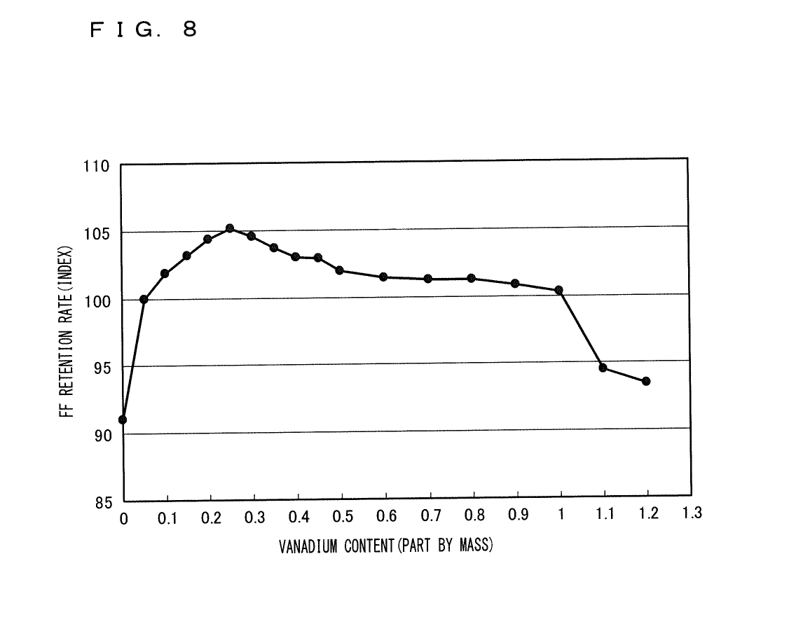

Then, electrodes of the solar cell element were formed. The front surface electrode was formed by applying any of the silver pastes prepared by mixing silver powder, Al₂O₃—SiO₂—PbO based glass frit and an organic vehicle in proportions by mass of 85:5:10 and further mixing 0 parts by mass to 1.2 parts by mass of elemental vanadium as shown in FIG. 8 relative to 100 parts by mass of silver in a liner pattern as shown in FIG. 1 by screen printing, and drying the applied silver paste.

Then, an aluminum paste was applied in a pattern of the rear surface collector electrodes 6b as shown in FIG. 5 on the rear surface side of the silicon substrate, followed by drying. Then, the same silver paste as used for the front surface electrode was applied in a pattern of the second power extraction electrodes 6a as shown in FIG. 5, then dried, and fired for 3 minutes under the condition of 750° C. in peak temperature.

Thus solar cell elements were prepared.

For each vanadium content, 30 solar cells were prepared. These samples were placed in a constant temperature constant humidity tester with a temperature of 125° C. and a humidity of 95%, and the fill factor (FF) retention rate after 200 hours was measured. The FF retention rates are represented by index with respect to the FF retention rate after 200 hours of the sample having a vanadium content of 0.05 part by mass, at which the index is 100, as shown in FIG. 8. This property was measured under the condition of AM 1.5 and irradiation of 100 mW/cm² in accordance with JIS C 8913, and then each average thereof is calculated.

The results in FIG. 8 shows that when the vanadium content was 0.25 part by mass, the FF retention rate came to the highest, and that when it was in the range of 0.05 part by mass to 1 part by mass, the variation in the FF retention rate of the solar cell element was reduced after the constant temperature constant humidity test. It was thus found that a vanadium content in such a range is effective in enhancing the reliability of the solar cell element. In addition, it was also found that the FF retention rate is particularly high when the vanadium content is in the range of 0.2 part by mass to 0.3 part by mass.

<Case 3>

Samples subjected to the steps before forming electrodes were prepared in the same manner using the same semiconductor substrate as in Case 1.

The front surface electrode 5 was formed by applying any of the silver pastes prepared by mixing silver powder, Al₂O₃—SiO₂—PbO based glass frit and an organic vehicle in proportions by mass of 85:5:10 and optionally further mixing elemental rhodium, a rhodium hydrate or an acetylene rhodium derivative so as to have the compositions of Examples 1 to 3 or Comparative Example 1 shown in Table 1 in a liner pattern as shown in FIG. 1 by screen printing, and drying the applied silver paste.

Then, an aluminum paste was applied in a pattern of the rear surface collector electrodes 6b as shown in FIG. 5 on the rear surface side of the silicon substrate, followed by drying. Then, a silver paste was applied in a pattern of the second power extraction electrodes 6a as shown in FIG. 5, then dried, and fired for 3 minutes under the condition of 750° C. in peak temperature.

Thus solar cell elements of Examples 1 to 3 and Comparative Example 1 were prepared.

For each of Examples 1 to 3 and Comparative Example 1, 30 solar cell elements were prepared. Then, the output power characteristics (fill factor (FF) and highest output power (Pmax)) were measured for evaluation. The results are shown in Table 1. These properties were measured under the condition of AM 1.5 and irradiation of 100 mW/cm² in accordance with JIS C 8913, and then each average thereof is calculated.

TABLE 1

| | | | Solar cell | |
|---|---|---|---|---|
| | Additive to silver paste | | properties | |
| | | Content | (relative to | |
| | | (relative to | the value of | |
| | | 100 parts | Comparative | |
| | | by mass of | Example 1 of 100) | |
| | Additive | silver powder) | FF | Pmax |
| Example 1 | Rhodium | 0.07 | 107 | 109 |
| | (element) | | | |
| Example 2 | Rhodium | 0.07 | 110 | 111 |
| | hydrate | | | |
| | (Rh₂O₃•5H₂O) | | | |
| Example 3 | Acetylene | 0.07 | 112 | 115 |
| | rhodium | | | |
| | derivative | | | |
| Comparative | None | — | 100 | 100 |
| Example 1 | | | | |

It was shown that the solar cell elements of Examples 1 to 3 exhibited improved FF values and higher output power in comparison with the solar cell elements of Comparative Example 1. It was thus confirmed that the addition of elemental rhodium, rhodium hydrate or an organic metal compound of rhodium to the conductive paste mainly containing silver is effective in increasing the photoelectric conversion efficiency of the solar cell.

<Case 4>

The same semiconductor substrate as used in Case 1 was subjected to the steps before forming electrodes in the same manner as in Case 1.

The front surface electrodes of solar cell elements were formed by applying any of the copper pastes prepared by mixing copper powder, Al₂O₃—SiO₂—PbO based glass frit and an organic vehicle in proportions by mass of 85:5:10 and optionally further mixing either elemental rhodium or a rhodium acetylene derivative so as to have the compositions of Examples 4 and 5 or Comparative Example 2 shown in Table 2 in a liner pattern as shown in FIG. 1 by screen printing, and drying the applied copper paste.

Then, an aluminum paste was applied in a pattern of the rear surface collector electrodes 6b as shown in FIG. 5 on the rear surface side of the silicon substrate, followed by drying. Then, a copper paste was applied in a pattern of the second power extraction electrodes 6a as shown in FIG. 5, then dried, and fired for 3 minutes in a nitrogen atmosphere under the condition of 650° C. in peak temperature.

Thus solar cell elements of Examples 4 and 5 and Comparative Example 2 were prepared.

For each of Examples 4 and 5 and Comparative Example 2, 30 solar cell elements were prepared, and the output power characteristics (fill factor (FF) and highest output power (Pmax)) of the solar cell elements were measured for evaluation. The results are shown in Table 2. These properties were measured under the condition of AM 1.5 and irradiation of 100 mW/cm² in accordance with JIS C 8913, and then each average thereof is calculated.

TABLE 2

| | | | Solar cell | |
|---|---|---|---|---|
| | Additive to copper paste | | properties | |
| | | Content | (relative to | |
| | | (relative to | the value of | |
| | | 100 parts | Comparative | |
| | | by mass of | Example 2 of 100) | |
| | Additive | copper powder) | FF | Pmax |
| Example 4 | Rhodium | 0.07 | 105 | 106 |
| | (element) | | | |
| Example 5 | Acetylene | 0.07 | 108 | 109 |
| | rhodium | | | |
| | derivative | | | |
| Comparative | None | — | 100 | 100 |
| Example 2 | | | | |

It was shown that the solar cell elements of Examples 4 and 5 exhibited improved FF values and higher output power in comparison with the solar cell elements of Comparative Example 2. It was thus confirmed that the addition of elemental rhodium or an organic metal compound of rhodium to the conductive paste mainly containing copper is effective in increasing the photoelectric conversion efficiency of the solar cell. In particular, the addition of an organic metal compound of rhodium was effective in increasing the photoelectric conversion efficiency of the solar cell.

<Case 5>

The same semiconductor substrate as used in Case 1 was subjected to the steps before forming electrodes in the same manner as in Case 1.

The front surface electrodes 5 of solar cell elements were formed by applying any of the pastes prepared by mixing silver and copper powder, Al₂O₃—SiO₂—PbO based glass frit and an organic vehicle in proportions by mass of 85:5:10 and optionally further mixing a rhodium acetylene derivative of Examples 6 and 7 shown in Table 3 and 4 so as to have the compositions of Comparative Examples 3 and 4 shown in Tables 3 and 4 in a liner pattern as shown in FIG. 1 by screen printing, and drying the applied paste.

Then, an aluminum paste was applied in a pattern of the rear surface collector electrodes 6b as shown in FIG. 5 on the rear surface 9b side, followed by drying. Then, a silver-copper paste was applied in a pattern of the second power extraction electrodes 6a as shown in FIG. 5, then dried, and fired for 3 minutes in a nitrogen atmosphere under the condition of 750° C. in peak temperature.

Thus solar cell elements were prepared.

For each of Examples 6 and 7 and Comparative Examples 3 and 4, 30 solar cell elements were prepared, and the output power characteristics (fill factor (FF) and highest output power (Pmax)) of the solar cell elements were measured for evaluation. The results are shown in Tables 3 and 4. These properties were measured under the condition of AM 1.5 and irradiation of 100 mW/cm² in accordance with JIS C 8913, and then each average thereof is calculated.

TABLE 3

| | | | | Solar cell | |
|---|---|---|---|---|---|
| | | | | properties | |
| | | | | (relative to | |
| | Ag—Cu contet ratio | | | the value of | |
| | | | Acetylene | Comparative | |
| | Proportion | Proportion | rhodium | Example 3 of 100) | |
| | of Ag | of Cu | derivative*¹ | FF | Pmax |
| Example 6 | 80 | 20 | 0.07 | 105 | 106 |
| Comparative | 80 | 20 | 0 | 100 | 100 |
| Example 3 | | | | | |

*¹Part by mass of rhodium relative to 100 parts by mass of Ag and Cu

TABLE 4

| | | | | Solar cell | |
|---|---|---|---|---|---|
| | | | | properties | |
| | | | | (relative to | |
| | Ag—Cu contet ratio | | | the value of | |
| | | | Acetylene | Comparative | |
| | Proportion | Proportion | rhodium | Example 4 of 100) | |
| | of Ag | of Cu | derivative*¹ | FF | Pmax |
| Example 7 | 50 | 50 | 0.07 | 107 | 108 |
| Comparative | 50 | 50 | 0 | 100 | 100 |
| Example 4 | | | | | |

*¹Part by mass of rhodium relative to 100 parts by mass of Ag and Cu

It was shown that the solar cell elements of Examples 6 and 7 shown in Tables 3 and 4 exhibited improved FF values and higher output power in comparison with the solar cell elements of Comparative Examples 3 and 4. It was thus confirmed that the addition of an organic metal compound of rhodium to the conductive paste mainly containing silver and copper is effective in increasing the photoelectric conversion efficiency of the solar cell.

<Case 6>

The same semiconductor substrate as used in Case 1 was subjected to the steps before forming electrodes in the same manner as in Case 1.

The front surface electrodes of solar cell elements were formed by applying any of the silver pastes prepared by mixing silver powder, Al₂O₃—SiO₂—PbO based glass frit and an organic vehicle in proportions by mass of 85:5:10 and optionally further mixing a material so as to have the compositions of Examples 1 and 2 and the Comparative Example shown in Table 5 in a liner pattern as shown in FIG. 1 by screen printing, and drying the applied silver paste.

Then, an aluminum paste was applied in a pattern of the rear surface collector electrodes 6b as shown in FIG. 5 on the rear surface side of the silicon substrate, followed by drying. Then, a silver paste was applied in a pattern of the second power extraction electrodes 6a as shown in FIG. 5, then dried, and fired for 3 minutes under the condition of 750° C. in peak temperature.

Thus solar cell elements 10 were prepared. For each of Examples 8 and 9 and Comparative Example 5, 30 solar cell elements 10 were prepared, and the fill factor (FF), which is one of the output power characteristics, of the solar cell elements was measured. Then, the solar cell elements were placed in a constant temperature constant humidity tester with a temperature of 125° C. and a humidity of 95%, and the fill factor (FF) retention rates after 200 hours and 350 hours were measured. The retention rates are represented by the percentages of those after 200 hours and 350 hours relative to the initial FF value 100%. These properties were measured under the condition of AM 1.5 and irradiation of 100 mW/cm² in accordance with JIS C 8913, and then each average thereof is calculated.

TABLE 5

| | | | | FF retention rate | |
|---|---|---|---|---|---|
| | | | Initial FF value | (%) after 125° C., | |
| | Content in silver paste | | (relative to | 95% constant temperature | |
| | (part by mass relative to | | the value of | constant humidity test | |
| | 100 parts by mass of silver) | | Comparative Example | After | After |
| | Vanadium | Rhodium | 5 of 100) | 200 hours | 350 hours |
| Example 8 | 0.25 | 0.07 | 102 | 97 | 63 |
| Example 9 | 0 | 0.07 | 105 | 95 | 54 |
| Comparative | 0 | 0 | 100 | 93 | 48 |
| Example 5 | | | | | |

As shown in Table 5, Example 8, in which rhodium and vanadium were added to the silver paste, exhibited higher FF retention rate than Comparative Example 5 and Example 9 in which only rhodium was added, in the constant temperature constant humidity test. It was thus shown that the reliability was more enhanced than the other samples. It was thus confirmed that the addition of both rhodium and vanadium is effective in increasing the FF retention rate and enhancing the reliability.

<Case 7>

Then, the same semiconductor substrate as used in Case 1 was subjected to the steps before forming electrodes in the same manner as in Case 1.

The front surface electrodes of solar cell elements were formed by applying any of the silver pastes prepared by mixing silver powder, Al₂O₃—SiO₂—PbO based glass frit and an organic vehicle in proportions by mass of 85:5:10 and further adding materials so as to have the compositions of Examples 10 to 21 shown in Table 6 in a liner pattern as shown in FIG. 1 by screen printing, and drying the applied silver paste.

Then, an aluminum paste was applied in a pattern of the rear surface collector electrodes 6b as shown in FIG. 5 on the rear surface side of the silicon substrate, followed by drying. Then, a silver paste was applied in a pattern of the second power extraction electrodes 6a as shown in FIG. 5, then dried, and fired for 3 minutes under the condition of 750° C. in peak temperature.

Thus solar cell elements were prepared. For each of Examples 10 to 21, 30 solar cell elements were prepared, and the fill factor (FF), which is one of the output power characteristics, of the solar cell elements was measured. Furthermore, the solar cell elements were placed in a constant temperature constant humidity tester with a temperature of 125° C. and a humidity of 95%, and the fill factor (FF) retention rates after 200 hours and hours were measured. The retention rates are represented by the percentages of those after 200 hours and 350 hours relative to the initial FF value 100%. These properties were measured under the condition of AM 1.5 and irradiation of 100 mW/cm² in accordance with JIS C 8913, and then each average thereof is calculated.

TABLE 6

| | Vanadium | | | | | |
|---|---|---|---|---|---|---|
| | content in | Glass frit | Rhodium | | | |
| | glass frit | content | content | Initial FF | | |
| | (part by | (part by | (part by | value | | |
| | mass relative | mass relative | mass relative | (relative to | FF retention rate (%) after 125 | |
| | to 100 parts | to 100 parts | to 100 parts | the value of | ° C., 95% constant temperature | |
| | by mass of | by mass of | by mass of | Example 21 | constant humidity test | |
| | glass frit) | silver) | silver) | of 100) | After 200 hours | After 350 hours |
| Example 10 | 5 | 0.5 | 0.07 | 106 | 84 | 42 |
| Example 11 | 5 | 1 | 0.07 | 107 | 92 | 76 |
| Example 12 | 5 | 3 | 0.07 | 104 | 94 | 80 |
| Example 13 | 5 | 4.5 | 0.07 | 106 | 96 | 85 |
| Example 14 | 5 | 5 | 0.07 | 110 | 97 | 87 |
| Example 15 | 5 | 6.5 | 0.07 | 108 | 96 | 85 |
| Example 16 | 5 | 8 | 0.07 | 105 | 93 | 83 |
| Example 17 | 5 | 10 | 0.07 | 105 | 94 | 82 |
| Example 18 | 5 | 13 | 0.07 | 106 | 93 | 83 |
| Example 19 | 5 | 15 | 0.07 | 104 | 92 | 82 |
| Example 20 | 5 | 16 | 0.07 | 101 | 93 | 81 |
| Example 21 | 5 | 17 | 0.07 | 100 | 93 | 82 |

The results showed that when the glass frit content was in the range of 1 part by mass to 15 parts by mass relative to 100 parts by mass of silver, in particular, the initial FF value was high and the FF retention rate was also high. Also, it was shown that when the glass frit content is in the range of 4.5 parts by mass to 6.5 parts by mass, the initial FF value and the FF retention rate are best.

<Case 8>

Then, the same semiconductor substrate as used in Case 1 was subjected to the steps before forming electrodes in the same manner as in Case 1.

The front surface electrodes of solar cell elements were formed by applying the silver paste prepared by mixing silver powder, Al₂O₃—SiO₂—PbO based glass frit holding vanadium and rhodium on the surfaces of the glass particles thereof, and an organic vehicle in proportions by mass of 85:5:10 and further adjusting the compositions to those of Example 22 and Comparative Example 6 shown in Table 7 in a liner pattern as shown in FIG. 1 by screen printing, and drying the applied silver paste.

Then, an aluminum paste was applied in a pattern of the rear surface collector electrodes 6b as shown in FIG. 5 on the rear surface side of the silicon substrate, followed by drying. Then, a silver paste was applied in a pattern of the second power extraction electrodes 6a as shown in FIG. 5, then dried, and fired for 3 minutes under the condition of 750° C. in peak temperature.

Thus solar cell elements were prepared. For each of Example 22 and Comparative Example 6, 30 solar cell elements were prepared, and the fill factor (FF), which is one of the output power characteristics, of the solar cell elements was measured for evaluation. Furthermore, the solar cell elements were placed in a constant temperature constant humidity tester with a temperature of 125° C. and a humidity of 95%, and the fill factor (FF) retention rates after 200 hours and hours were measured. The retention rates are represented by the percentages of those after 200 hours and 350 hours relative to the initial FF value 100%. These properties were measured under the condition of AM 1.5 and irradiation of 100 mW/cm² in accordance with JIS C 8913, and then each average thereof is calculated.

TABLE 7

| | | | | FF retention rate | |
|---|---|---|---|---|---|
| | | | Initial FF value | (%) after 125° C., | |
| | Content in silver paste | | (relative to | 95% constant temperature | |
| | (part by mass relative to | | the value of | constant humidity test | |
| | 100 parts by mass of silver) | | Comparative Example | Aftrer | After |
| | Vanadium | Rhodium | 6 of 100) | 200 hours | 350 hours |
| Example 22 | 0.25 | 0.07 | 102 | 97 | 80 |
| Comparative | 0 | 0 | 100 | 88 | 42 |
| Example 6 | | | | | |

The results showed that the FF retention rate of Example 22 was particularly high even after 350 hours, and higher than the FF retention rate of Example 8 in case 6. Thus, it was confirmed that the FF retention rate is increased by making vanadium and rhodium held on the surfaces of glass particles.

The above-described Examples are merely few of the examples. Niobium and tantalum, which are group 5 elements other than vanadium and similar to vanadium in chemical characteristics, or rhenium and osmium, which are similar to rhodium in chemical characteristics, also produced substantially the same results when added to the conductive paste.

### DESCRIPTION OF THE REFERENCE NUMERALS

1: semiconductor substrate
2: one conductivity type layer
3: opposite conductivity type layer
4: antireflection layer (antireflection film)
5: front surface electrode
5a front surface power extraction electrode
5b: front surface collector electrode
5c: auxiliary electrode
6: rear surface electrode
6a: rear surface power extraction electrode
6b: rear surface collector electrode
7, 14: BSF region
9a: front surface (light-receiving surface)
9b: rear surface (non-light-receiving surface)
9c: side surface
10: solar cell element (solar cell)
11: first passivation layer
12: second passivation layer

1. A conductive paste for solar cell electrodes, comprising:
a glass frit containing a large number of glass particles; and
a non-glass component containing mainly at least one of silver and copper, and additionally metallic element A1,
wherein the metallic element A1 is at least one selected from the group consisting of vanadium, niobium, tantalum, rhodium, rhenium, and osmium.

2. The conductive paste for solar cell electrodes according to claim 1, wherein the non-glass component contains metal elements A2 and A3 as the metallic element A1, and
wherein the metallic element A2 is at least one selected from the group consisting of vanadium, niobium, and tantalum, and
the metallic element A3 is at least one selected from the group consisting of rhodium, rhenium, and osmium.

3. The conductive paste for solar cell electrodes according to claim 1, wherein the non-glass component contains at least one of vanadium and rhodium as the metallic element A1.

4. The conductive paste for solar cell electrodes according to claim 1, wherein the metallic element A1 is held at the surface of at least one of the glass particles and the metal mainly added to the non-glass component.

5. The conductive paste for solar cell electrodes according to claim 2, wherein the metallic element A2 and the metallic element A3 are held at the surface of at least one of the glass particles and the metal mainly added to the non-glass component.

6. The conductive paste for solar cell electrodes according to claim 5, wherein the metallic element A2 is vanadium, and the metallic element A3 is rhodium.

7. The conductive paste for solar cell electrodes according to claim 3, wherein the non-glass component contains vanadium as the metallic element A1 in a proportion in the range of 0.05 part by mass to 1 part by mass relative to 100 parts by mass of at least one of silver and copper.

8. The conductive paste for solar cell electrodes according to claim 3, wherein the non-glass component contains rhodium as the metallic element A1 in a proportion in the range of 0.06 part by mass to 0.5 part by mass relative to 100 parts by mass of at least one of silver and copper.

9. The conductive paste for solar cell electrodes according to claim 1, wherein the glass particles contain at least one metallic element selected from the group consisting of vanadium, niobium, and tantalum, and the metallic element A1 is at least one selected from the group consisting of rhenium, rhenium, and osmium.

10. The conductive paste for solar cell electrodes according to claim 9, wherein the glass particles contain vanadium, and the metallic element A1 is rhodium.

11. The conductive paste for solar cell electrodes according to claim 10, wherein the glass particles contain 0.2 part by mass to 20 parts by mass of vanadium relative to 100 parts by mass of the glass frit, and the non-glass component contains 0.06 part by mass to 1.2 parts by mass of rhodium relative to 100 parts by mass of the at least one of silver and copper.

12. A solar cell comprising:
a semiconductor substrate;
an antireflection film disposed in a first region on a main surface of the semiconductor substrate; and
an electrode disposed in a second region different from the first region on the main surface of the semiconductor substrate and formed by firing the conductive paste for solar cell electrodes as set forth in claim 1.

13. A method for manufacturing a solar cell including a semiconductor substrate, an antireflection film disposed in a first region on a main surface of the semiconductor substrate, and an electrode disposed in a second region different from the first region on the main surface of the semiconductor substrate, the method comprising:
forming the antireflection film on the main surface of the semiconductor substrate;
applying the conductive paste for solar cell electrodes as set forth in claim 1 onto the antireflection film in an electrode pattern, and
firing the conductive paste to remove the portion of the antireflection film under the conductive paste, thereby disposing the antireflection film in the first region on the main surface of the semiconductor substrate and disposing the electrode formed by firing the conductive paste in the second region on the main surface of the semiconductor substrate.
